(19) United States
(12) Patent Application Publication
(10) Pub. No.: US 2024/0224761 A1
(43) Pub. Date: Jul. 4, 2024

(54) DISPLAY DEVICE AND METHOD OF FABRICATING THE SAME

(71) Applicant: Samsung Display Co., LTD., Yongin-si (KR)

(72) Inventors: Joon Yong PARK, Yongin-si (KR); Hyun Eok SHIN, Yongin-si (KR); Ju Hyun LEE, Yongin-si (KR); Yung Bin CHUNG, Yongin-si (KR)

(21) Appl. No.: 18/376,088

(22) Filed: Oct. 3, 2023

(30) Foreign Application Priority Data
Dec. 30, 2022 (KR) 10-2022-0191211

(51) Int. Cl. H10K 59/80; H10K 59/12; H10K 59/122

(52) U.S. Cl. CPC H10K 59/8791; H10K 59/1201; H10K 59/122

(57) ABSTRACT

A display device includes a first pixel electrode disposed in a first emission area on a substrate, an insulating layer covering an edge of the first pixel electrode, a first emissive layer disposed on the first pixel electrode and the insulating layer, a first common electrode disposed on the first emissive layer, a bank disposed on the insulating layer to surround the first emission area, a low-reflection insulating layer disposed on the bank, a first organic pattern surrounding the first emission area on the low-reflection insulating layer and including a same material as a material of the first emissive layer. The bank includes a first bank disposed on the insulating layer and contacts the first common electrode, a second bank disposed on the first bank, a third bank disposed on the second bank, and a fourth bank disposed on the third bank. The first to fourth banks include metal materials.

This application claims priority to Korean Patent Application No. 10-2022-0191211, filed on Dec. 30, 2022, and all the benefits accruing therefrom under 35 U.S.C. § 119, the content of which in its entirety is herein incorporated by reference.

### BACKGROUND

### 1. Field

The disclosure relates to a display device and a method of fabricating the same.

### 2. Description of the Related Art

As an information-oriented society evolves, various demands for display devices are ever increasing. For example, display devices are being employed by a variety of electronic devices such as smart phones, digital cameras, laptop computers, navigation devices, and smart televisions. Display devices may be flat panel display devices such as a liquid-crystal display device, a field emission display device, and an organic light-emitting display device. Among such flat panel display devices, a light-emitting display device includes a light-emitting element that may emit light on its own, so that each of the pixels of the display panel may emit light by themselves. Accordingly, a light-emitting display device may display images without a backlight unit that supplies light to the display panel.

### SUMMARY

Features of the disclosure provide a display device that may reduce the reflection of external light and improve the display quality, and a method of fabricating the same.

It should be noted that features of the disclosure are not limited to the above-mentioned feature; and other features of the disclosure will be apparent to those skilled in the art from the following descriptions.

In an embodiment of the disclosure, a display device includes a first pixel electrode disposed in a first emission area on a substrate, an insulating layer covering an edge of the first pixel electrode, a first emissive layer disposed on the first pixel electrode and the insulating layer, a first common electrode disposed on the first emissive layer, a bank disposed on the insulating layer to surround the first emission area, a low-reflection insulating layer disposed on the bank, a first organic pattern surrounding the first emission area on the low-reflection insulating layer and including a same material as that of the first emissive layer. The bank includes a first bank disposed on the insulating layer and in contact with the first common electrode, a second bank disposed on the first bank, a third bank disposed on the second bank, and a fourth bank disposed on the third bank. The first to fourth banks include metal materials.

In an embodiment, the first bank may include aluminum, the second bank may include titanium, the third bank may include titanium oxide or aluminum nitride, and the fourth bank may include titanium or titanium nitride.

In an embodiment, a thickness of the first bank may be greater than a sum of thicknesses of the second to fourth banks.

In an embodiment, the thickness of the second bank may range from approximately 300 angstroms (Å) to approximately 600 Å, the thickness of the third bank may range from approximately 200 Å to approximately 400 Å, and the thickness of the fourth bank may range from approximately 100 Å to approximately 200 Å.

In an embodiment, a side surface of the first bank may be recessed inward from a side surface of the second bank.

In an embodiment, the low-reflection insulating layer may include a first layer disposed on the fourth bank, a second layer disposed on the first layer, and a third layer disposed on the second layer.

In an embodiment, the first to third layers may include different inorganic layers from each other.

In an embodiment, the first layer may include silicon oxynitride, the second layer may include silicon nitride, and the third layer may include silicon oxide.

In an embodiment, a thickness of the first layer may range from approximately 500 Å to approximately 1,500 Å, a thickness of the second layer may range from approximately 4,000 Å to approximately 5,000 Å, and a thickness of the third layer may range from approximately 4,000 Å to approximately 5,000 Å.

In an embodiment, the first layer may have a refractive index of approximately 1.7 to approximately 1.8, the second layer may have a refractive index of approximately 1.85 to approximately 1.9, and the third layer may have a refractive index of approximately 1.45 to approximately 1.55.

In an embodiment, a thickness of the second or third layer may be greater than a sum of thicknesses of the second to fourth banks.

In an embodiment, the display device may further include a second pixel electrode disposed in a second emission area on the substrate, a second emissive layer disposed on the second pixel electrode, and a second common electrode disposed on the second emissive layer.

In an embodiment, the first and second common electrodes may be electrically connected with each other through the first bank.

In an embodiment of the disclosure, a method of fabricating a display device includes forming first and second pixel electrodes on a substrate, stacking a sacrificial layer, an insulating layer, a bank and a low-reflection insulating layer on the first and second pixel electrodes, exposing the first pixel electrode by etching the low-reflection insulating layer, the bank, the insulating layer and the sacrificial layer, and forming a first emissive layer on the first pixel electrode and forming a first organic pattern on the low-reflection insulating layer. The bank includes a first bank disposed on the insulating layer and in contact with a first common electrode, a second bank disposed on the first bank, a third bank disposed on the second bank, and a fourth bank disposed on the third bank. The first to fourth banks include metal materials.

In an embodiment, the exposing the first pixel electrode may include etching a side surface of the first bank more than a side surface of the second bank to form a protruding tip of the second bank.

In an embodiment, the forming the first emissive layer and forming the first organic pattern may include cutting an organic material deposited on the substrate by the protruding tip of the second bank to separate the first emissive layer and the first organic pattern from each other.

In an embodiment, the first bank may include aluminum, the second bank may include titanium, the third bank may include titanium oxide or aluminum nitride, and the fourth bank may include titanium or titanium nitride.

In an embodiment, the thickness of the second bank may range from approximately 300 Å to approximately 600 Å, the thickness of the third bank may range from approximately 200 Å to approximately 400 Å, and the thickness of the fourth bank may range from approximately 100 Å to approximately 200 Å.

In an embodiment, the low-reflection insulating layer may include a first layer disposed on the fourth bank, a second layer disposed on the first layer, and a third layer disposed on the second layer.

In an embodiment, the first layer may include silicon oxynitride, the second layer may include silicon nitride, and the third layer may include silicon oxide.

By embodiments of the disclosure, a display device includes a bank consisting of multiple films including a metal material having relatively low reflectance, and a low-reflection insulating layer consisting of multiple films including an inorganic material having relatively low reflectance, and may reduce the reflection of external light and improve the display quality.

It should be noted that effects of the disclosure are not limited to those described above and other effects of the disclosure will be apparent to those skilled in the art from the following descriptions.

### BRIEF DESCRIPTION OF THE DRAWINGS

The above and other embodiments, advantages and features of the disclosure will become more apparent by describing in detail embodiments thereof with reference to the attached drawings, in which:

FIG. 1 is a perspective view showing an embodiment of a display device according to the disclosure.

FIG. 2 is a cross-sectional view showing an embodiment of a display device according to the disclosure.

FIG. 3 is a plan view showing a display unit of an embodiment of a display device according to the disclosure.

FIG. 4 is a cross-sectional view showing a part of an embodiment of a display device according to the disclosure.

FIG. 5 is an enlarged view of area A1 of FIG. 4.

FIGS. 6 to 13 are cross-sectional views showing an embodiment of processing steps of fabricating a display device according to the disclosure.

### DETAILED DESCRIPTION

In the following description, for the purposes of explanation, numerous specific details are set forth in order to provide a thorough understanding of various embodiments or implementations of the disclosure. As used herein “embodiments” and “implementations” are interchangeable words that are non-limiting embodiments of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or features, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. The term “approximately” or “about” can mean within one or more standard deviations, or within ±30%, 20%, 10%, 5% of the stated value, for example

Various embodiments are described herein with reference to cross-sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure is described with reference to the accompanying drawings.

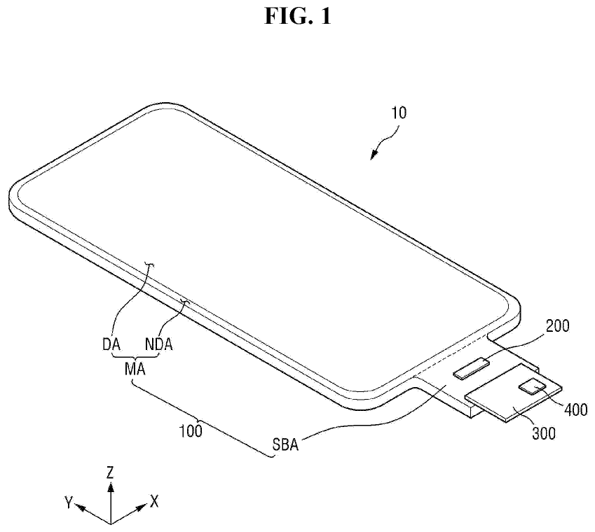

FIG. 1 is a perspective view showing an embodiment of a display device according to the disclosure.

Referring to FIG. 1, a display device 10 may be employed by portable electronic devices such as a mobile phone, a smart phone, a tablet personal computer (PC), a mobile communications terminal, an electronic notebook, an electronic book, a portable multimedia player (“PMP”), a navigation device and an ultra mobile PC (“UMPC”). In an embodiment, the display device 10 may be used as a display unit of a television, a laptop computer, a monitor, an electronic billboard, or the Internet of Things (“IoT”), for example. In another embodiment, the display device 10 may be applied to wearable devices such as a smart watch, a watch phone, a glasses-type display, and a head-mounted display (“HMD”) device.

The display device 10 may have a shape similarly to a quadrangular shape when viewed from the top. In an embodiment, the display device 10 may have a shape similar to a quadrangle having shorter sides in the x-axis direction and longer sides in the y-axis direction when viewed from the top, for example. The corners where the shorter sides in the x-axis direction and the longer sides in the y-axis direction meet may be rounded to have a predetermined curvature or may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include a display area DA having pixels for displaying images, and a non-display area NDA disposed around the display area DA. The display area DA may emit light from a plurality of emission areas or a plurality of opening areas. In an embodiment, the display panel 100 may include a pixel circuit including switching elements, a pixel-defining layer that defines the emission areas or the opening areas, and a self-light-emitting element, for example.

In an embodiment, the self-light-emitting element may include, but is not limited to, at least one of an organic light-emitting diode including an organic emissive layer, a quantum-dot light-emitting diode (“quantum LED”) including a quantum-dot emissive layer, an inorganic light-emitting diode (“inorganic LED”) including an inorganic semiconductor, and a micro light-emitting diode (“micro LED”), for example.

The non-display area NDA may be disposed on the outer side of the display area DA. The non-display area NDA may be defined as the edge area of the main area MA of the display panel 100. The non-display area NDA may include a gate driver (not shown) that applies gate signals to gate lines, and fan-out lines (not shown) that connect the display driver 200 with the display area DA.

The subsidiary area SBA may be extended from one side of the main area MA. The subsidiary area SBA may include a flexible material that may be bent, folded, or rolled. In an embodiment, when the subsidiary area SBA is bent, the subsidiary area SBA may overlap the main area MA in the thickness direction (z-axis direction), for example. The subsidiary area SBA may include pads connected to the display driver 200 and the circuit board 300. Optionally, the subsidiary area SBA may be eliminated, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (“IC”) and may be attached on the display panel 100 by a chip-on-glass (“COG”) technique, a chip-on-plastic (“COP”) technique, or ultrasonic bonding. In an embodiment, the display driver 200 may be disposed in the subsidiary area SBA and may overlap with the main area MA in the thickness direction (z-axis direction) when the subsidiary area SBA is bent, for example. In another embodiment, the display driver 200 may be disposed (e.g., mounted) on the circuit board 300, for example.

The circuit board 300 may be attached on the pads of the display panel 100 using an anisotropic conductive film (“ACF”). Lead lines of the circuit board 300 may be electrically connected to the pads of the display panel 100. The circuit board 300 may be a flexible printed circuit board (“FPCB”), a printed circuit board (“PCB”), or a flexible film such as a chip-on-film (“COF”).

The touch driver 400 may be disposed (e.g., mounted) on the circuit board 300. The touch driver 400 may be electrically connected to a touch sensing unit of the display panel 100. The touch driver 400 may supply a touch driving signal to a plurality of touch electrodes of the touch sensing unit and may sense a change in the capacitance between the plurality of touch electrodes. In an embodiment, the touch driving signal may be a pulse signal having a predetermined frequency, for example. The touch driver 400 may determine whether there is an input and may find the coordinates of the input based on the amount of the change in the capacitance between the touch electrodes. The touch driver 400 may be implemented as an IC.

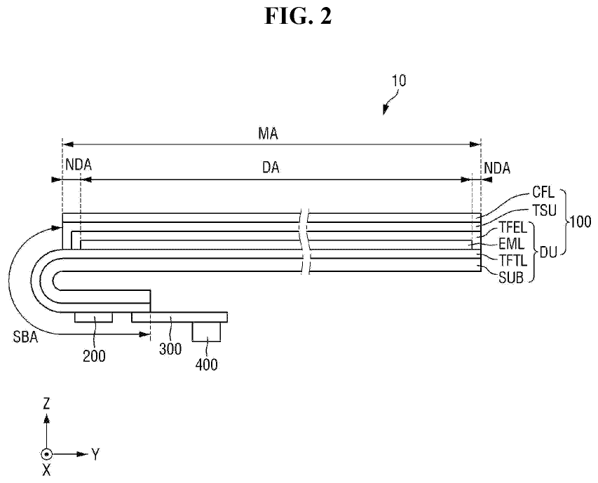

FIG. 2 is a cross-sectional view showing an embodiment of a display device according to the disclosure.

Referring to FIG. 2, the display panel 100 may include a display unit DU, a touch sensing unit TSU, and a color filter layer CFL. The display unit DU may include a substrate SUB, a thin-film transistor layer TFTL, an emission material layer EML and an encapsulation layer TFEL.

The substrate SUB may be a base substrate or a base member. The substrate SUB may be a flexible substrate that may be bent, folded, or rolled. In an embodiment, the substrate SUB may include, but is not limited to, a polymer resin such as polyimide PI, for example. In another embodiment, the substrate SUB may include a glass material or a metal material, for example.

The thin-film transistor layer TFTL may be disposed on the substrate SUB. The thin-film transistor layer TFTL may include a plurality of thin-film transistors forming pixel circuits of pixels. The thin-film transistor layer TFTL may include gate lines, data lines, voltage lines, gate control lines, fan-out lines for connecting the display driver 200 with the data lines, lead lines for connecting the display driver 200 with the pads, etc. Each of the thin-film transistors may include a semiconductor region, a source electrode, a drain electrode, and a gate electrode. In an embodiment, when the gate driver is formed on one side of the non-display area NDA of the display panel 100, the gate driver may include thin-film transistors, for example.

The thin-film transistor layer TFTL may be disposed in the display area DA, the non-display area NDA and the subsidiary area SBA. The thin-film transistors in each of the pixels, the gate lines, the data lines and the voltage lines in the thin-film transistor layer TFTL may be disposed in the display area DA. The gate control lines and the fan-out lines in the thin-film transistor layer TFTL may be disposed in the non-display area NDA. The lead lines of the thin-film transistor layer TFTL may be disposed in the subsidiary area SBA.

The emission material layer EML may be disposed on the thin-film transistor layer TFTL. The emission material layer EML may include a plurality of light-emitting elements in each of which a pixel electrode, an emissive layer and a common electrode are stacked on one another sequentially to emit light, and a pixel-defining film for defining the pixels. The plurality of light-emitting elements in the emission material layer EML may be disposed in the display area DA.

In an embodiment, the emissive layer may be an organic emissive layer including an organic material, for example. The emissive layer may include a hole transporting layer, an organic light-emitting layer and an electron transporting layer. When the pixel electrode receives a voltage and the common electrode receives a cathode voltage through the thin-film transistors in the thin-film transistor layer TFTL, the holes and electrons may move to the organic light-emitting layer through the hole transporting layer and the electron transporting layer, respectively, such that they combine in the organic light-emitting layer to emit light. In an embodiment, the pixel electrode may be an anode electrode while the common electrode may be a cathode electrode, for example. It is, however, to be understood that the disclosure is not limited thereto.

In another embodiment, the light-emitting elements may include quantum-dot light-emitting diodes each including a quantum-dot emissive layer, inorganic light-emitting diodes each including an inorganic semiconductor, or micro light-emitting diodes.

An encapsulation layer TFEL may cover the upper and side surfaces of the emission material layer EML, and may protect the emission material layer EML. The encapsulation layer TFEL may include at least one inorganic layer and at least one organic layer for encapsulating the emission material layer EML.

The touch sensing unit TSU may be disposed on the encapsulation layer TFEL. The touch sensing unit TSU may include a plurality of touch electrodes for sensing a user's touch by capacitive sensing, and touch lines connecting the plurality of touch electrodes with the touch driver 400. In an embodiment, the touch sensing unit TSU may sense a user's touch by mutual capacitance sensing or self-capacitance sensing, for example.

In another embodiment, the touch sensing unit TSU may be disposed on a separate substrate disposed on the display unit DU, for example. In such case, the substrate supporting the touch sensing unit TSU may be a base member encapsulating the display unit DU.

The plurality of touch electrodes of the touch sensing unit TSU may be disposed in a touch sensor area overlapping with the display area DA. The touch lines of the touch sensing unit TSU may be disposed in a touch peripheral area overlapping with the non-display area NDA.

The color filter layer CFL may be disposed on the touch sensing unit TSU. The color filter layer CFL may include a plurality of color filters associated with the plurality of emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL may prevent distortion of colors due to the reflection of external light.

Since the color filter layer CFL is disposed directly on the touch sensing unit TSU, the display device 10 may desire no separate substrate for the color filter layer CFL. Therefore, the thickness of the display device 10 may be relatively reduced.

The subsidiary area SBA of the display panel 100 may be extended from one side of the main area MA. The subsidiary area SBA may include a flexible material that may be bent, folded, or rolled. In an embodiment, when the subsidiary area SBA is bent, the subsidiary area SBA may overlap the main area MA in the thickness direction (z-axis direction), for example. The subsidiary area SBA may include pads electrically connected to the display driver 200 and the circuit board 300.

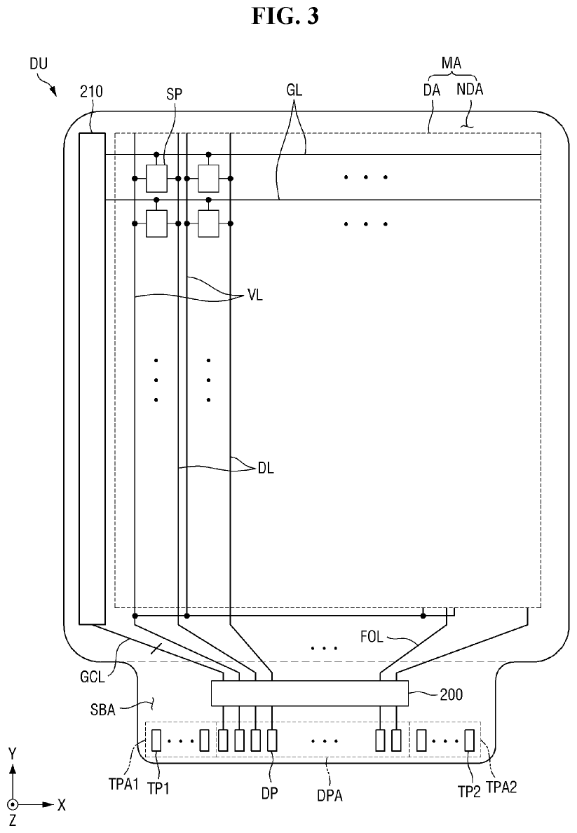

FIG. 3 is a plan view showing an embodiment of a display unit of a display device according to the disclosure.

Referring to FIG. 3, the display unit DU may include a display area DA and a non-display area NDA.

The display area DA displays images therein and may be defined as a central area of the display panel 100. The display area DA may include a plurality of pixels SP, a plurality of gate lines GL, a plurality of data lines DL and a plurality of voltage lines. Each of the plurality of pixels SP may be defined as the minimum unit that outputs light.

The plurality of gate lines GL may supply the gate signals received from the gate driver 210 to the plurality of pixels SP. The plurality of gate lines GL may be extended in the x-axis direction and may be spaced apart from one another in the y-axis direction crossing the x-axis direction.

The plurality of data lines DL may supply the data voltages received from the display driver 200 to the plurality of pixels SP. The plurality of data lines DL may be extended in the y-axis direction and may be spaced apart from one another in the x-axis direction.

The plurality of voltage lines VL may supply the supply voltage received from the display driver 200 to the plurality of pixels SP. The supply voltage may be at least one of a driving voltage, an initialization voltage, a reference voltage and a low-level voltage. The plurality of voltage lines VL may be extended in the y-axis direction and may be spaced apart from one another in the x-axis direction.

The non-display area NDA may surround the display area DA. The non-display area NDA may include the gate driver 210, fan-out lines FOL, and gate control lines GCL. The gate driver 210 may generate a plurality of gate signals based on the gate control signal, and may sequentially supply the plurality of gate signals to the plurality of gate lines GL in a predetermined order.

The fan-out lines FOL may be extended from the display driver 200 to the display area DA. The fan-out lines FOL may supply the data voltage received from the display driver 200 to the plurality of data lines DL.

A gate control line GCL may be extended from the display driver 200 to the gate driver 210. The gate control line GCL may supply the gate control signal received from the display driver 200 to the gate driver 210.

The subsidiary area SBA may include the display driver 200, a display pad area DPA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels SP, so that the luminance of the plurality of pixels SP may be determined. The display driver 200 may supply a gate control signal to the gate driver 210 through the gate control line GCL.

The display pad area DPA, the first touch pad area TPA1 and the second touch pad area TPA2 may be disposed on the edge of the subsidiary area SBA. The display pad area PA, the first touch pad area TPA1 and the second touch pad area TPA2 may be electrically connected to the circuit board 300 using a low-resistance, high-reliable material such as an anisotropic conductive film and a self assembly anisotropic conductive paste (“SAP”).

The display pad area DPA may include a plurality of display pads DP. The plurality of display pads DP may be electrically connected to a graphic system through the circuit board 300. The plurality of display pads DP may be connected to the circuit board 300 to receive digital video data and may supply the digital video data to the display driver 200.

The first touch pad area TPA1 may be disposed on one side of the display pad area DPA and may include a plurality of first touch pads TP1. The plurality of first touch pads TP1 may be electrically connected to the touch driver 400 disposed on the circuit board 300. The plurality of first touch pads TP1 may supply touch driving signals to a plurality of driving electrodes through a plurality of driving lines.

The second touch pad area TPA2 may be disposed on the opposite side of the display pad area DPA and may include a plurality of second touch pads TP2. The plurality of second touch pads TP2 may be electrically connected to the touch driver 400 disposed on the circuit board 300. The touch driver 400 may receive a touch sensing signal through a plurality of sensing lines connected to the plurality of second touch pads TP2, and may sense a change in the capacitance between the driving electrodes and sensing electrodes.

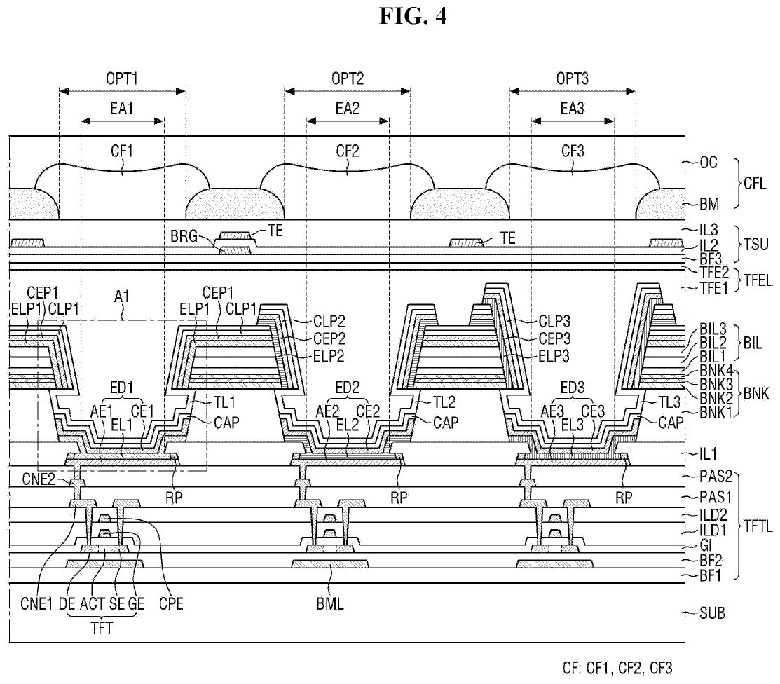

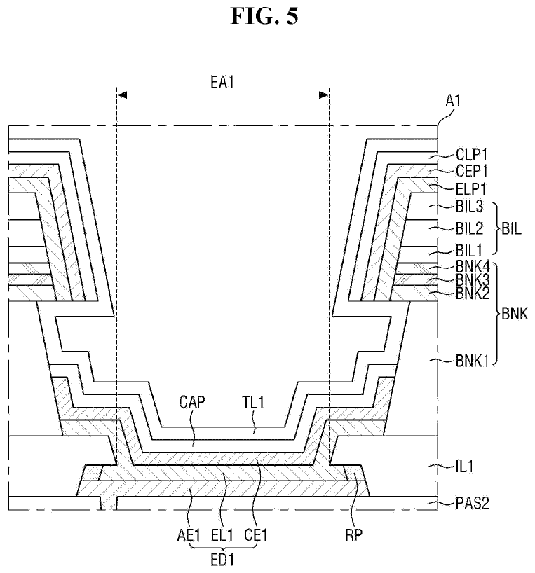

FIG. 4 is a cross-sectional view showing an embodiment of apart of a display device according to the disclosure. FIG. 5 is an enlarged view of area A1 of FIG. 4.

Referring to FIGS. 4 and 5, the display panel 100 may include the display unit DU, the touch sensing unit TSU, and the color filter layer CFL. The display unit DU may include a substrate SUB, a thin-film transistor layer TFTL, an emission material layer EML and an encapsulation layer TFEL.

The substrate SUB may be a base substrate or a base member. The substrate SUB may be a flexible substrate that may be bent, folded, or rolled. In an embodiment, the substrate SUB may include, but is not limited to, a polymer resin such as polyimide PI, for example. In another embodiment, the substrate SUB may include a glass material or a metal material.

The thin-film transistor layer TFTL may include a first buffer layer BF1, a light-blocking layer BML, a second buffer layer BF2, a thin-film transistor TFT, a gate insulator GI, a first inter-dielectric layer ILD1, a capacitor electrode CPE, a second inter-dielectric layer ILD2, a first connection electrode CNE1, a first passivation layer PAS1, a second connection electrode CNE2 and a second passivation layer PAS2.

The first buffer layer BF1 may be disposed on the substrate SUB. The first buffer layer BF1 may include an inorganic film capable of preventing permeation of air or moisture. In an embodiment, the first buffer layer BF1 may include a plurality of inorganic layers stacked on one another alternately, for example.

The light-blocking layer BML may be disposed on the first buffer layer BF1. In an embodiment, the light-blocking layer BML may consist of a single layer or multiple layers of one of molybdenum (Mo), aluminum (Al), chromium (Cr), gold (Au), titanium (Ti), nickel (Ni), neodymium (Nd) and copper (Cu) or any alloys thereof, for example. In another embodiment, the light-blocking layer BML may be an organic layer including a black pigment, for example.

The second buffer layer BF2 may be disposed on the first buffer layer BF1 and the light-blocking layer BML. The second buffer layer BF2 may include an inorganic film capable of preventing permeation of air or moisture. In an embodiment, the second buffer layer BF2 may include a plurality of inorganic layers stacked on one another alternately, for example.

The thin-film transistor TFT may be disposed on the second buffer layer BF2 and may form a pixel circuit of each of a plurality of pixels. In an embodiment, the thin-film transistor TFT may be a driving transistor or a switching transistor of the pixel circuit, for example. The thin-film transistor TFT may include a semiconductor region ACT, a source electrode SE, a drain electrode DE and a gate electrode GE.

The semiconductor region ACT, the source electrode SE and the drain electrode DE may be disposed on the second buffer layer BF2. The semiconductor region ACT, the source electrode SE and the drain electrode DE may overlap with the light-blocking layer BML in the thickness direction. The semiconductor region ACT may overlap with the gate electrode GE in the thickness direction and may be insulated from the gate electrode GE by the gate insulator GI. The source electrode SE and the drain electrode DE may be formed by converting the material of the semiconductor region ACT into a conductor.

The gate electrode GE may be disposed on the gate insulator GI. The gate electrode GE may overlap with the semiconductor region ACT with the gate insulator GI interposed therebetween.

The gate insulator GI may be disposed on the semiconductor region ACT, the source electrode SE and the drain electrode DE. In an embodiment, the gate insulator GI may cover the semiconductor region ACT, the source electrode SE, the drain electrode DE and the second buffer layer BF2, and may insulate the semiconductor region ACT from the gate electrode GE, for example.

The first inter-dielectric layer ILD1 may be disposed on the gate electrode GE and the gate insulator GI. The first inter-dielectric layer ILD1 may insulate the gate electrode GE from the capacitor electrode CPE.

The capacitor electrode CPE may be disposed on the first inter-dielectric layer ILD1. The capacitor electrode CPE may overlap with the gate electrode GE in the thickness direction. The capacitor electrode CPE and the gate electrode GE may form a capacitance.

The second inter-dielectric layer ILD2 may be disposed on the capacitor electrode CPE and the first inter-dielectric layer ILD1. The second inter-dielectric layer ILD2 may insulate the capacitor electrode CPE from the first connection electrode CNE1.

The first connection electrode CNE1 may be disposed on the second inter-dielectric layer ILD2. The first connection electrode CNE1 may electrically connect the drain electrode DE of the thin-film transistor TFT with the second connection electrode CNE2. The first connection electrode CNE1 may be inserted into a contact hole defined in the second inter-dielectric layer ILD2, the first inter-dielectric layer ILD1, and the gate insulator GI to contact the drain electrode DE of the thin-film transistor TFT.

The first passivation layer PAS1 may be disposed on the first connection electrode CNE1 and the second inter-dielectric layer ILD2. The first passivation layer PAS1 may protect the thin-film transistor TFT. The first passivation layer PAS1 may insulate the first connection electrode CNE1 from the second connection electrode CNE2.

The second connection electrode CNE2 may be disposed on the first passivation layer PAS1. The second connection electrode CNE2 may electrically connect the first connection electrode CNE1 with a first pixel electrode AE1 of a first light-emitting element ED1. The second connection electrode CNE2 may be inserted into a contact hole defined in the first passivation layer PAS1 to contact the first connection electrode CNE1.

The second passivation layer PAS2 may be disposed on the second connection electrode CNE2 and the first passivation layer PAS1. The second passivation layer PAS2 may insulate the second connection electrode CNE2 from the first pixel electrode AE1.

The emission material layer EML may be disposed on the thin-film transistor layer TFTL. The emission material layer EML may include the first to third light-emitting elements ED1, ED2 and ED3, a remaining pattern RP, a first insulating layer IL1, a capping layer CAP, a bank BNK, a low-reflection insulating layer BIL, first to third organic patterns ELP1, ELP2 and ELP3, first to third electrode patterns CEP1, CEP2 and CEP3, first to third capping patterns CLP1, CLP2 and CLP3, and first to third inorganic layers TL1, TL2 and TL3.

Each of the display devices 10 may include a plurality of pixels arranged in rows and columns in the display area DA. Each of the plurality of pixels may include first to third emission areas EA1, EA2 and EA3 defined by the bank BNK or the pixel-defining film, and may emit light having a predetermined peak wavelength through the first to third emission areas EA1, EA2 and EA3. In the first to third emission areas EA1, EA2 and EA3, lights generated by the light-emitting elements of the display device 10 exit out of the display device 10.

The first to third emission areas EA1, EA2 and EA3 may emit light having predetermined peak wavelengths to the outside of the display devices 10. The first emission area EA1 may emit light of a first color, the second emission area EA2 may emit light of a second color, and the third emission area EA3 may emit light of a third color. In an embodiment, the light of the first color may be red light having a peak wavelength in the range of approximately 610 nanometers (nm) to approximately 650 nm, the light of the second color may be green light having a peak wavelength in the range of approximately 510 nm to approximately 550 nm, and the light of the third color may be blue light having a peak wavelength in the range of approximately 440 nm to approximately 480 nm, for example. It is, however, to be understood that the disclosure is not limited thereto.

In an embodiment, the size of the third emission area EA3 may be larger than the size of the first emission area EA1, and the size of the first emission area EA1 may be larger than the size of the second emission area EA2, for example. It should be understood, however, that the disclosure is not limited thereto. In another embodiment, the size of the first emission area EA1, the size of the second emission area EA2 and the size of the third emission area EA3 may be substantially all equal, for example.

The first light-emitting element ED1 may be disposed in the first emission area EA1 on the thin-film transistor layer TFTL. The first light-emitting element ED1 may include a first pixel electrode AE1, a first emissive layer EL1, and a first common electrode CE1. The second light-emitting element ED2 may be disposed in the second emission area EA2 on the thin-film transistor layer TFTL. The second light-emitting element ED2 may include a second pixel electrode AE2, a second emissive layer EL2, and a second common electrode CE2. The third light-emitting element ED3 may be disposed in the third emission area EA3 on the thin-film transistor layer TFTL. The third light-emitting element ED3 may include a third pixel electrode AE3, a third emissive layer EL3, and a third common electrode CE3.

The first to third pixel electrodes AE1, AE2 and AE3 may be disposed on the second passivation layer PAS2. Each of the first to third pixel electrodes AE1, AE2 and AE3 may be electrically connected to the drain electrode DE of the thin-film transistor TFT through the first and second connection electrodes CNE1 and CNE2. The first to third pixel electrodes AE1, AE2 and AE3 may be insulated from one another by the first insulating layer IL1. In an embodiment, the first to third pixel electrodes AE1, AE2 and AE3 may include at least one of silver (Ag), copper (Cu), aluminum (Al), nickel (Ni) and lanthanum (La), for example. In another embodiment, each of the first to third pixel electrodes AE1, AE2 and AE3 may include a material such as indium tin oxide (“ITO”), indium zinc oxide (“IZO”) and indium tin zinc oxide (“ITZO”), for example. In another embodiment, each of the first to third pixel electrodes AE1, AE2 and AE3 may have a stack structure such as ITO/Ag/ITO/, ITO/Ag/IZO and ITO/Ag/ITZO/IZO.

The first insulating layer IL may be disposed on the second passivation layer PAS2 and the remaining pattern RP. The first insulating layer IL1 may cover the edges of the first to third pixel electrodes AE1, AE2 and AE3 and the remaining pattern RP, and may expose a part of the upper surface of each of the first to third pixel electrodes AE1, AE2 and AE3. In an embodiment, the first insulating layer IL1 may expose the first pixel electrode AE1 in the first emission area EA1, and the first emissive layer EL1 may be disposed directly on the first pixel electrode AE1, for example. The first insulating layer IL1 may include an inorganic insulating material. The first insulating layer IL1 may include, but is not limited to, at least one of a silicon nitride layer, a silicon oxynitride layer, a silicon oxide layer, a titanium oxide layer, an aluminum oxide layer, and an amorphous silicon layer.

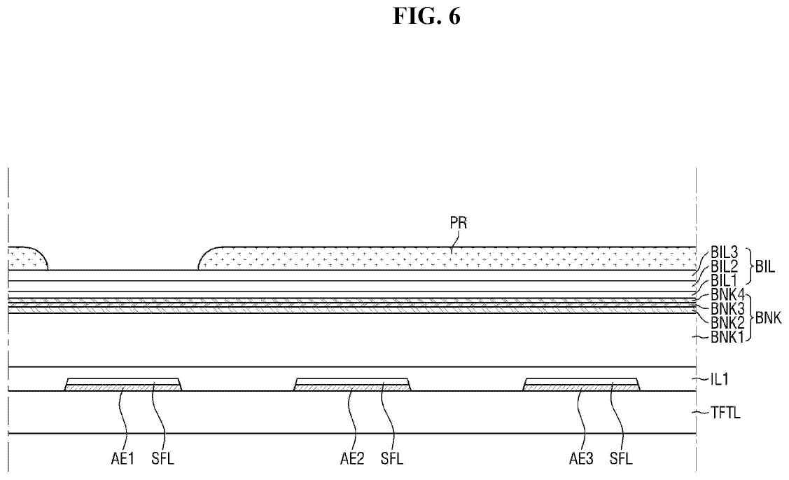

The remaining pattern RP may be disposed on edges of each of the first to third pixel electrodes AE1, AE2 and AE3. The first insulating layer IL1 may not be in directly contact with the upper surface of each of the first to third pixel electrodes AE1, AE2 and AE3 by the remaining pattern RP. The remaining pattern RP may be formed by removing a sacrificial layer SFL (refer to FIG. 6) disposed on the first to third pixel electrodes AE1, AE2 and AE3 in the process of fabricating the display device 10.

The first to third emissive layers EL1, EL2 and EL3 may be organic emissive layers including organic materials and may be formed on the first to third pixel electrodes AE1, AE2 and AE3 via a deposition process. In an embodiment, in the process of depositing the first to third emissive layers EL1, EL2 and EL3, the organic material may be deposited in a direction inclined from the upper surface of the substrate SUB, for example.

The first emissive layer EL1 may be disposed directly on the first pixel electrode AE1 in the first emission area EA1. A part of the first emissive layer EL1 may be disposed in the space surrounded by the first pixel electrode AE1, the remaining pattern RP and the first insulating layer IL1, while other parts of the first emissive layer EL1 may cover a part of the upper surface and side surfaces of the first insulating layer IL1. The second emissive layer EL2 may be disposed directly on the second pixel electrode AE2 in the second emission area EA2. A part of the second emissive layer EL2 may be disposed in the space surrounded by the second pixel electrode AE2, the remaining pattern RP and the first insulating layer IL1, while other parts of the second emissive layer EL2 may cover a part of the upper surface and side surfaces of the first insulating layer IL1. The third emissive layer EL3 may be disposed directly on the third pixel electrode AE3 in the third emission area EA3. A part of the third emissive layer EL3 may be disposed in the space surrounded by the third pixel electrode AE3, the remaining pattern RP and the first insulating layer IL1, while other parts of the third emissive layer EL3 may cover a part of the upper surface and side surfaces of the first insulating layer IL1.

The first common electrode CE1 may be disposed on the first emissive layer EL1, the second common electrode CE2 may be disposed on the second emissive layer EL2, and the third common electrode CE3 may be disposed on the third emissive layer EL3. The first to third common electrodes CE1, CE2 and CE3 may include a transparent conductive material and may transmit light generated in the first to third emissive layers EL1, EL2 and EL3. The first to third common electrodes CE1, CE2 and CE3 may contact the side surfaces of the first bank BNK1, and the first to third common electrodes CE1, CE2 and CE3 may be electrically connected with one another by the first bank BNK1. In an embodiment, the first to third common electrodes CE1, CE2 and CE3 may receive a common voltage or a low-level voltage, for example.

The first pixel electrode AE1 may receive a voltage equal to the data voltage from the thin-film transistor TFT, and the first common electrode CE1 may receive a common voltage or a cathode voltage. In this instance, since a potential difference is formed between the first pixel electrode AE1 and the first common electrode CE1, holes and electrons may move to the first emissive layer EL1 through the hole transport layer and the electron transport layer, respectively, so that the first emissive layer EL1 may emit light.

The capping layer CAP may be disposed on the first to third common electrodes CE1, CE2 and CE3. The capping layer CAP may include an inorganic insulating material and may cover the first to third light-emitting elements ED1, ED2 and ED3. The capping layer CAP may prevent the first to third light-emitting elements ED1, ED2 and ED3 from being damaged by outside air. In an embodiment, the capping layer CAP may include, but is not limited to, at least one of a silicon nitride layer, a silicon oxynitride layer, a silicon oxide layer, a titanium oxide layer, an aluminum oxide layer, and an amorphous silicon layer, for example.

The bank BNK may be disposed on the first insulating layer IL1 to define first to third emission areas EA1, EA2 and EA3. The bank BNK may surround the first to third emission areas EA1, EA2 and EA3 when viewed from the top. The bank BNK may overlap with a light-blocking member BM of the color filter layer CFL. The bank BNK may include first to fourth banks BNK1, BNK2, BNK3 and BNK4.

The first bank BNK1 may be disposed on the first insulating layer IL1, the second bank BNK2 may be disposed on the first bank BNK1, the third bank BNK3 may be disposed on the second bank BNK2, and the fourth bank BNK4 may be disposed on the third bank BNK3. The side surfaces of the first bank BNK1 may be recessed inward from the side surfaces of the second bank BNK2. Since the side surface of the second bank BNK2 protrude from the side surface of the first bank BNK1 toward the first light-emitting element EA1, the second bank BNK2 may include a protruding tip. Accordingly, an undercut structure may be formed under the tip of the second bank BNK2. The thickness of the first bank BNK1 may be greater than that of the second bank BNK2.

The first bank BNK1 may include a different metal material from that of the second to fourth banks BNK2, BNK3 and BNK4. The etch rate of the first bank BNK1 may be different from the etch rates of the second to fourth banks BNK2, BNK3 and BNK4. In an embodiment, in a wet etching process, the etch rate of the first bank BNK1 may be higher than that of the second to fourth banks BNK2, BNK3 and BNK4, and the first bank BNK1 may be etched more than the second to fourth banks BNK2, BNK3 and BNK4 in the process of defining the first to third emission areas EA1, EA2 and EA3, for example. Accordingly, the shapes of the side surfaces of the first to fourth banks BNK1, BNK2, BNK3 and BNK4 may be determined by a difference in the etch rates between the first to fourth banks BNK1, BNK2, BNK3 and BNK4.

The first bank BNK1 may include a metal material having relatively high electrical conductivity. The first bank BNK1 may electrically connect the first to third common electrodes CE1, CE2 and CE3 spaced apart from one another.

The second to fourth banks BNK2, BNK3 and BNK4 may include a metal material having relatively low reflectance. In an embodiment, the first bank BNK1 may include aluminum (Al), the second and fourth banks BNK2 and BNK4 may include titanium (Ti), and the third bank BNK3 may include titanium oxide (TiOx), for example. It should be understood, however, that the disclosure is not limited thereto. In another embodiment, the second bank BNK2 may include titanium (Ti), the third bank BNK3 may include titanium oxide (TiOx), and the fourth bank BNK4 may include titanium nitride (TiNx), for example. In another embodiment, the second and fourth banks BNK2 and BNK4 may include titanium (Ti), and the third bank BNK3 may include aluminum nitride (AlNx). In another embodiment, the second bank BNK2 may include titanium (Ti), the third bank BNK3 may include aluminum nitride (AlNx), and the fourth bank BNK4 may include titanium nitride (TiNx).

The thickness of the second bank BNK2 may range from approximately 300 angstroms (Å) to approximately 600 Å, the thickness of the third bank BNK3 may range from approximately 200 Å to approximately 400 Å, and the thickness of the fourth bank BNK4 may range from approximately 100 Å to approximately 200 Å. It should be understood, however, that the disclosure is not limited thereto. The thickness of the first bank BNK1 may be greater than the sum of the thicknesses of the second to fourth banks BNK2, BNK3 and BNK4, but the disclosure is not limited thereto.

The second to fourth banks BNK2, BNK3 and BNK4 may be sequentially stacked on the glass to have reflectances as shown in Table 1 below. The second bank BNK2 used in the measurement of Table 1 includes titanium (Ti) and has the thickness of 500 Å. The third bank BNK3 used in the measurement of Table 1 includes titanium oxide (TiOx) and has the thickness of 300 Å. The fourth bank BNK4 used in the measurement of Table 1 includes titanium (Ti) and has the thickness of 100 Å. The average reflectance may correspond to the average value of reflectances for lights having wavelengths of 380 nm to 780 nm.

TABLE 1

| Average Reflectance | 450 nm | 550 nm | 650 nm |
|---|---|---|---|
| 14.1% | 12.5% | 12.0% | 13.2% |

In an embodiment, a single film of titanium (Ti) having the thickness of 1,000 Å may have a reflectance of approximately 52% in a visible light region (550 nm), for example. The display device 10 may include a multilayer including the second to fourth banks BNK2, BNK3 and BNK4 to have a relatively low reflectance in the visible light region (550 nm). As the display device 10 includes the second to fourth banks BNK2, BNK3 and BNK4 having relatively low reflectance, it is possible to reduce the reflectance of external light and improve the display quality.

The low-reflection insulating layer BIL may be disposed on the bank BNK. The low-reflection insulating layer BIL may surround the first to third emission areas EA1, EA2 and EA3 when viewed from the top. The low-reflection insulating layer BIL may overlap with a light-blocking member BM of the color filter layer CFL. The low-reflection insulating layer BIL may further include first to third layers BIL1, BIL2 and BIL3.

The first layer BIL1 may be disposed on the bank BNK, the second layer BIL2 may be disposed on the first layer BIL1, and the third layer BIL3 may be disposed on the second layer BIL2. The first to third layers BIL1, BIL2 and BIL3 may include a material having relatively low reflectance. The first to third layers BIL1, BIL2 and BIL3 may include different inorganic layers. In an embodiment, the first layer BIL1 may include silicon oxynitride (SiONx), the second layer BIL2 may include silicon nitride (SiNx), and the third layer BIL3 may include silicon oxide (SiOx), for example. It should be understood, however, that the disclosure is not limited thereto.

The thickness of the first layer BIL1 may range from approximately 500 Å to approximately 1,500 Å, the thickness of the second layer BIL2 may range from approximately 4,000 Å to approximately 5,000 Å, and the thickness of the third layer BIL3 may range from approximately 4,000 Å to approximately 5,000 Å. It should be understood, however, that the disclosure is not limited thereto. The thickness of the second or third layers BIL2 or BIL3 may be greater than the sum of thicknesses of the second to fourth banks BNK2, BNK3 and BNK4. When the display device 10 includes a tip structure consisting of a single metal film on the first bank BNK1, the tip structure of the single metal film may sag or may be deformed. The first to third layers BIL1, BIL2 and BIL3 are disposed on the bank BNK to support the tip structure of the second to fourth banks BNK2, BNK3 and BNK4, so that it is possible to prevent the tip structure from sagging or being deformed. Accordingly, the display device 10 includes the first to third layers BIL1, BIL2 and BIL3 disposed on the bank BNK to stably maintain the function of the tip structure, so that an organic material or an inorganic material may be cut and separated in the deposition process.

The refractive index of the first layer BIL1 may range from approximately 1.7 to approximately 1.8, the refractive index of the second layer BIL2 may range from approximately 1.85 to approximately 1.9, and the refractive index of the third layer BIL3 may range from approximately 1.45 to approximately 1.55. It should be understood, however, that the disclosure is not limited thereto.

The second and third layers BIL2 and BIL3 may be sequentially stacked on the glass to have reflectances as shown in Table 2 below. The first to third layers BIL1, BIL2 and BIL3 may be sequentially stacked on the glass to have reflectances as shown in Table 2 below. The first layer BIL1 used in the measurement of Table 2 includes silicon oxynitride (SiONx) and has the thickness of 1,000 Å. The second layer BIL2 used in the measurement of Table 2 includes silicon nitride (SiNx) and has the thickness of 4,500 Å. The third layer BIL3 used in the measurement of Table 2 includes silicon oxide (SiOx) and has the thickness of 4,000 Å. The average reflectance may correspond to the average value of reflectances for lights having wavelengths of 400 nm to 780 nm.

TABLE 2

| | Average Reflectance | 450 nm | 550 nm | 650 nm |
|---|---|---|---|---|
| Second and Third | 14.3% | 8.6% | 8.4% | 19.5% |
| Layers BIL2 and BIL3 | | | | |
| First to Third Layers | 7.7% | 11.2% | 8.3% | 4.3% |
| BIL1, BIL2 and BIL3 | | | | |

The display device 10 includes the first to third layers BIL1, BIL2 and BIL3 disposed on the bank BNK and may have a relatively low reflectance in the visible light region (550 nm). As the display device 10 includes the first to third layers BIL1, BIL2 and BIL3 having relatively low reflectance, it is possible to reduce the reflectance of external light and improve the display quality.

The bank BNK may form the first to third emission areas EA1, EA2 and EA3 via a mask process, and the first to third emissive layers EL1, EL2 and EL3 may be disposed in the first to third emission areas EA1, EA2 and EA3, respectively. To perform a mask process, a structure for holding the mask may be desired. In order to control the deviations of the mask process, an excessively wide area of the non-display area NDA may be desired. Accordingly, by reducing the mask process, it is possible to eliminate a structure for holding the mask, and to reduce the non-display area NDA for deviation control.

The first to third light-emitting elements ED1, ED2 and ED3 may be formed via deposition and etching processes instead of a mask process. Since the first bank BNK1 includes a different metal material than the second to fourth banks BNK2, BNK3 and BNK4, the inner wall of the bank BNK may have the tip structure. The display device 10 may form different layers in each of the first to third emission areas EA1, EA2 and EA3 via the deposition process. In an embodiment, the first emissive layer EL1 and the first organic pattern ELP1 may be deposited using the same organic material via a deposition process without using a mask and may be cut by the tip formed on the inner wall of the bank BNK, for example. The first emissive layer EL1 may be disposed in the first emission area EA1, and the first organic pattern ELP1 may be disposed between the first to third emission areas EA1, EA2 and EA3 on the bank BNK and the low-reflection insulating layer BIL.

The organic material for forming the first emissive layer EL1 may be deposited on the entirety of the surface of the display device 10, and the organic material of the first emissive layer EL1 deposited on the second and third emission areas EA2 and EA3 may be removed. The organic material for forming the second emissive layer EL2 may be deposited on the entirety of the surface of the display device 10, and the organic material of the second emissive layer EL2 deposited on the first and third emission areas EA1 and EA3 may be removed. The organic material for forming the third emissive layer EL3 may be deposited on the entirety of the surface of the display device 10, and the organic material of the third emissive layer EL3 deposited on the first and second emission areas EA1 and EA2 may be removed. In this manner, the display device 10 may form different organic materials in the first to third emission areas EA1, EA2 and EA3, respectively, via deposition and etching processes without using a mask process. By eliminating unnecessary processes, it is possible to save the fabrication costs of the display device 10, and to reduce the non-display area NDA.

The first organic pattern ELP1 may include the same organic material as that of the first emissive layer EL 1 and may be disposed on the low-reflection insulating layer BIL. The first organic pattern ELP1 may cover the side surfaces of the second to fourth banks BNK2, BNK3 and BNK4 and the low-reflection insulating layer BIL which are adjacent to the first emission area EA1. The first emissive layer EL1 and the first organic pattern ELP1 may be deposited via the same process, and may be cut and separated by the tip formed on the inner wall of the bank BNK. Accordingly, the first organic pattern ELP1 may be disposed on the low-reflection insulating layer BIL except the first to third emission areas EA1, EA2 and EA3.

The first electrode pattern CEP1 may include the same metal material as that of the first common electrode CE1 and may be disposed on the first organic pattern ELP1. The first electrode pattern CEP1 may cover a side surface of the first organic pattern ELP1 which is closer to the first emission area EA1. The first common electrode CE1 and the first electrode pattern CEP1 may be deposited via the same process, but may be cut by the tip formed on the inner wall of the bank BNK. Accordingly, the first electrode pattern CEP1 may be disposed on the first organic pattern ELP1 except the first to third emission areas EA1, EA2 and EA3.

The first capping pattern CLP1 may include the same inorganic material as that of the capping layer CAP and may be disposed on the first electrode pattern CEP1. The first capping pattern CLP1 may cover a side surface of the first electrode pattern CEP1 which is closer to the first emission area EA1. The capping layer CAP and the first capping pattern CLP1 may be deposited via the same process, but may be cut by the tip formed on the inner wall of the bank BNK. Accordingly, the first capping pattern CLP1 may be disposed on the first electrode pattern CEP1 except the first to third emission areas EA1, EA2 and EA3.

The first inorganic layer TL1 may be disposed on the capping layer CAP of the first emission area EA1 and the first capping pattern CLP1. The first inorganic layer TL1 may cover the side surfaces of the first bank BNK1 surrounding the first emission area EA1. The first inorganic layer TL1 includes an inorganic material to prevent oxygen or moisture from permeating into the first light-emitting element ED1. The first inorganic layer TL1 may be an inorganic encapsulation layer. In an embodiment, the first inorganic layer TL1 may include, but is not limited to, at least one of a silicon nitride layer, a silicon oxynitride layer, a silicon oxide layer, a titanium oxide layer, an aluminum oxide layer, and an amorphous silicon layer, for example.

A second organic pattern ELP2 may include the same organic material as that of the second emissive layer EL2 and may be disposed on the first inorganic layer TL1. The second organic pattern ELP2 may cover the side surfaces of the second to fourth banks BNK2, BNK3 and BNK4, the low-reflection insulating layer BIL, the first organic pattern ELP1, the first electrode pattern CEP1, the first capping pattern CLP1 and the first inorganic layer TL1, which are adjacent to the second emission area EA2. The second emissive layer EL2 and the second organic pattern ELP2 may be deposited via the same process, but may be cut by the tip formed on the inner wall of the bank BNK. Accordingly, the second organic pattern ELP2 may be disposed on the first inorganic layer TL1 where it is adjacent to the second and third emission areas EA2 and EA3.

The second electrode pattern CEP2 may include the same metal material as that of the second common electrode CE2 and may be disposed on the second organic pattern ELP2. The second electrode pattern CEP2 may cover a side surface of the second organic pattern ELP2 which is closer to the second emission area EA2. The second common electrode CE2 and the second electrode pattern CEP2 may be deposited via the same process, but may be cut by the tip formed on the inner wall of the bank BNK. Accordingly, the second electrode pattern CEP2 may be disposed on the second organic pattern ELP2 where it is adjacent to the second and third emission areas EA2 and EA3.

The second capping pattern CLP2 may include the same inorganic material as that of the capping layer CAP and may be disposed on the second electrode pattern CEP2. The second capping pattern CLP2 may cover a side surface of the second electrode pattern CEP2 which is closer to the second emission area EA2. The capping layer CAP and the second capping pattern CLP2 may be deposited via the same process, but may be cut by the tip formed on the inner wall of the bank BNK. Accordingly, the second capping pattern CLP2 may be disposed on the second electrode pattern CEP2 where it is adjacent to the second and third emission areas EA2 and EA3.

The second inorganic layer TL2 may be disposed on the capping layer CAP of the second emission area EA2 and the second capping pattern CLP2. The second inorganic layer TL2 may cover the side surfaces of the first bank BNK1 surrounding the second emission area EA2. The second inorganic layer TL2 includes an inorganic material to prevent oxygen or moisture from permeating into the second light-emitting element ED2. The second inorganic layer TL2 may be an inorganic encapsulation layer. In an embodiment, the second inorganic layer TL2 may include or consist of any of the above-listed materials for the first inorganic layer TL1, for example.

The third organic pattern ELP3 may include the same organic material as that of the third emissive layer EL3 and may be disposed on the second inorganic layer TL2. The third organic pattern ELP3 may cover the side surfaces of the second to fourth banks BNK2, BNK3 and BNK4, the low-reflection insulating layer BIL, the first organic pattern ELP1, the first electrode pattern CEP1, the first capping pattern CLP1, the first inorganic layer TL1, the second organic pattern ELP2, the second electrode pattern CEP2, the second capping pattern CLP2 and the second inorganic layer TL2, which are adjacent to the third emission area EA3. The third emissive layer EL3 and the third organic pattern ELP3 may be deposited via the same process, but may be cut by the tip formed on the inner wall of the bank BNK. Accordingly, the third organic pattern ELP3 may be disposed on the second inorganic layer TL2 where it is adjacent to the third emission area EA3.

The third electrode pattern CEP3 may include the same metal material as that of the third common electrode CE3 and may be disposed on the third organic pattern ELP3. The third electrode pattern CEP3 may cover a side surface of the third organic pattern ELP3 which is closer to the third emission area EA3. The third common electrode CE3 and the third electrode pattern CEP3 may be deposited via the same process, but may be cut by the tip formed on the inner wall of the bank BNK. Accordingly, the third electrode pattern CEP3 may be disposed on the third organic pattern ELP3 where it is adjacent to the third emission area EA3.

The third capping pattern CLP3 may include the same inorganic material as that of the capping layer CAP and may be disposed on the third electrode pattern CEP3. The third capping pattern CLP3 may cover a side surface of the third electrode pattern CEP3 which is closer to the third emission area EA3. The capping layer CAP and the third capping pattern CLP3 may be deposited via the same process, but may be cut by the tip formed on the inner wall of the bank BNK. Accordingly, the third capping pattern CLP3 may be disposed on the third electrode pattern CEP3 where it is adjacent to the third emission area EA3.

The third inorganic layer TL3 may be disposed on the capping layer CAP of the third emission area EA3 and the third capping pattern CLP3. The third inorganic layer TL3 may cover the side surfaces of the first bank BNK1 surrounding the third emission area EA3. The third inorganic layer TL3 includes an inorganic material to prevent oxygen or moisture from permeating into the third light-emitting element ED3. The third inorganic layer TL3 may be an inorganic encapsulation layer. In an embodiment, the third inorganic layer TL3 may include or consist of any of the above-listed materials for the first inorganic layer TL1, for example.

The encapsulation layer TFEL may be disposed on the first to third inorganic layers TL1, TL2 and TL3 to cover the emission material layer EML. The encapsulation layer TFEL may include first and second encapsulation layers TFE1 and TFE2.

The first encapsulation layer TFE1 may be disposed over the first to third inorganic layers TL1, TL2 and TL3 to provide a flat upper surface of the emission material layer EML. The first encapsulation layer TFE1 may include an organic material to protect the emission material layer EML from foreign substances such as dust. In an embodiment, the first encapsulation layer TFE1 may include an organic film such as an acrylic resin, an epoxy resin, a phenolic resin, a polyamide resin and a polyimide resin, for example. The first encapsulation layer TFE1 may be formed by curing a monomer or applying a polymer.

The second encapsulation layer TFE2 may be disposed on the first encapsulation layer TFE1. The second encapsulation layer TFE2 may include an inorganic material to prevent oxygen or moisture from permeating into the emission material layer EML. In an embodiment, the second encapsulation layer TFE2 may include, but is not limited to, at least one of a silicon nitride layer, a silicon oxynitride layer, a silicon oxide layer, a titanium oxide layer, an aluminum oxide layer, and an amorphous silicon layer, for example.

The touch sensing unit TSU may be disposed on the encapsulation layer TFEL. The touch sensing unit TSU may include a third buffer layer BF3, a bridge electrode BRG, a second insulating layer IL2, touch electrodes TE and a third insulating layer IL3.

The third buffer layer BF3 may be disposed on the encapsulation layer TFEL. The third buffer layer BF3 may be insulating and may have optical functions. The third buffer layer BF3 may include at least one inorganic layer. Optionally, the third buffer layer BF3 may be eliminated.

The bridge electrode BRG may be disposed on the third buffer layer BF3. The bridge electrode BRG may be disposed in a different layer from the touch electrodes TE to electrically connect between adjacent touch electrodes TE.

The second insulating layer IL2 may be disposed on the bridge electrode BRG and the third buffer layer BF3. The second insulating layer IL2 may be insulating and may have optical functions. In an embodiment, the second insulating layer IL2 may include, but is not limited to, at least one of a silicon nitride layer, a silicon oxynitride layer, a silicon oxide layer, a titanium oxide layer, an aluminum oxide layer, and an amorphous silicon layer, for example.

The touch electrodes TE may be disposed on the second insulating layer IL2. The touch electrodes TE may include driving electrodes and sensing electrodes, and may sense a change in mutual capacitance between the driving electrodes and the sensing electrodes. The touch electrodes TE may not overlap with the first to third emission areas EA1, EA2 and EA3. The touch electrodes TE may consist of a single layer of molybdenum (Mo), titanium (Ti), copper (Cu), aluminum (Al), or indium tin oxide (“ITO”), or may consist of a stack structure of aluminum and titanium (Ti/Al/Ti), a stack structure of aluminum and ITO (ITO/Al/ITO), an APC alloy and a stack structure of an APC alloy and ITO (ITO/APC/ITO).

The third insulating layer IL3 may be disposed on the touch electrodes TE and the second insulating layer IL2. The third insulating layer IL3 may be insulating and may have optical functions. The third insulating layer IL3 may include or consist of any of the above-listed materials for the first insulating layer IL1.

The color filter layer CFL may be disposed on the touch sensing unit TSU. The color filter layer CFL may include a light-blocking member BM, a plurality of color filters CF, and a planarization layer OC.

The light-blocking member BM may be disposed on the third insulating layer IL3 to surround first to third optical regions OPT1, OPT2 and OPT3. The light-blocking member BM may overlap the touch electrodes TE. The light-blocking member BM may include a light-absorbing material to prevent reflection of light. In an embodiment, the light-blocking member BM may include an inorganic black pigment, an organic black pigment, or an organic blue pigment, for example. The inorganic black pigment may be a metal oxide such as carbon black and titanium black. The organic black pigment may include at least one of lactam black, perylene black, and aniline black. The organic blue pigment may be C.I. pigment blue. It should be understood, however, that the disclosure is not limited thereto. The light-blocking member BM may prevent visible light from penetrating and mixing colors between the first to third emission areas EA1, EA2 and EA3 to improve the color gamut of the display device 10.

The plurality of color filters CF may include first to third color filters CF1, CF2 and CF3. The first to third color filters CF1, CF2 and CF3 may be disposed on the third insulating layer IL3 in line with the first to third emission areas EA1, EA2 and EA3, respectively.

The first color filter CF1 may be disposed on the third insulating layer IL3 in the first emission area EA1. The first color filter CF1 may be surrounded by the light-blocking member BM when viewed from the top. The edges of the first color filter CF1 may cover parts of the upper surface of the light-blocking member BM, but the disclosure is not limited thereto. The first color filter CF1 may selectively transmit light of the first color (e.g., red light) and may block and absorb light of the second color (e.g., green light) and light of the third color (e.g., blue light). In an embodiment, the first color filter CF1 may be a red color filter and may include a red colorant, for example.

The second color filter CF2 may be disposed on the third insulating layer IL3 in the second emission area EA2. The second color filter CF2 may be surrounded by the light-blocking member BM when viewed from the top. The edges of the second color filter CF2 may cover parts of the upper surface of the light-blocking member BM, but the disclosure is not limited thereto. The second color filter CF2 may selectively transmit light of the second color (e.g., green light) and may block and absorb light of the first color (e.g., red light) and light of the third color (e.g., blue light). In an embodiment, the second color filter CF2 may be a green color filter and may include a green colorant, for example.

The third color filter CF3 may be disposed on the third insulating layer IL3 in the third emission area EA3. The third color filter CF3 may be surrounded by the light-blocking member BM when viewed from the top. The edges of the third color filter CF3 may cover parts of the upper surface of the light-blocking member BM, but the disclosure is not limited thereto. The third color filter CF3 may selectively transmit light of the third color (e.g., blue light) and may block and absorb light of the first color (e.g., red light) and light of the second color (e.g., green light). In an embodiment, the third color filter CF3 may be a blue color filter and may include a blue colorant, for example.

The first to third color filters CF1, CF2 and CF3 may absorb a part of the light introduced from the outside of the display device 10 to reduce reflection of external light. Accordingly, the first to third color filters CF1, CF2 and CF3 may prevent color distortion due to reflection of external light.

The planarization layer OC may be disposed over the light-blocking member BM and the first to third color filters CF1, CF2 and CF3. The planarization layer OC may provide a flat surface over the color filter layer CFL. In an embodiment, the planarization layer OC may include an organic insulating material, for example.

FIGS. 6 to 13 are cross-sectional views showing an embodiment of processing steps of fabricating a display device according to the disclosure.

As shown in FIG. 6, first to third pixel electrodes AE1, AE2 and AE3 may be spaced apart from one another on a thin-film transistor layer TFTL. The first to third pixel electrodes AE1, AE2 and AE3 may include at least one of silver (Ag), copper (Cu), aluminum (Al), nickel (Ni) and lanthanum (La). In another embodiment, each of the first to third pixel electrodes AE1, AE2 and AE3 may include a material such as indium tin oxide (“ITO”), indium zinc oxide (“IZO”) and indium tin zinc oxide (“ITZO”). In another embodiment, each of the first to third pixel electrodes AE1, AE2 and AE3 may have a stack structure such as ITO/Ag/ITO/, ITO/Ag/IZO and ITO/Ag/ITZO/IZO.

A sacrificial layer SFL may be disposed on the first to third pixel electrodes AE1, AE2 and AE3. The sacrificial layer SFL may be disposed between the upper surfaces of the first to third pixel electrodes AE1, AE2 and AE3 and the first insulating layer ILL. The sacrificial layer SFL may include an oxide semiconductor. In an embodiment, the sacrificial layer SFL may include at least one of indium gallium zinc oxide (“IGZO”), zinc tin oxide (“ZTO”), and indium tin oxide (“IZO”), for example.

The first insulating layer IL1 may be disposed on the thin-film transistor layer TFTL and the sacrificial layer SFL. The first insulating layer IL1 may include an inorganic insulating material. The first insulating layer IL1 may include, but is not limited to, at least one of a silicon nitride layer, a silicon oxynitride layer, a silicon oxide layer, a titanium oxide layer, an aluminum oxide layer, and an amorphous silicon layer.

The bank BNK may include first to fourth banks BNK1, BNK2, BNK3 and BNK4. The first bank BNK1 may be disposed on the first insulating layer IL1, the second bank BNK2 may be disposed on the first bank BNK1, the third bank BNK3 may be disposed on the second bank BNK2, and the fourth bank BNK4 may be disposed on the third bank BNK3.

The first bank BNK1 may include a metal material having relatively high electrical conductivity. The second to fourth banks BNK2, BNK3 and BNK4 may include a metal material having relatively low reflectance. In an embodiment, the first bank BNK1 may include aluminum (Al), the second and fourth banks BNK2 and BNK4 may include titanium (Ti), and the third bank BNK3 may include titanium oxide (TiOx), for example. It should be understood, however, that the disclosure is not limited thereto. In another embodiment, the second bank BNK2 may include titanium (Ti), the third bank BNK3 may include titanium oxide (TiOx), and the fourth bank BNK4 may include titanium nitride (TiNx), for example. In another embodiment, the second and fourth banks BNK2 and BNK4 may include titanium (Ti), and the third bank BNK3 may include aluminum nitride (AlNx). In another embodiment, the second bank BNK2 may include titanium (Ti), the third bank BNK3 may include aluminum nitride (AlNx), and the fourth bank BNK4 may include titanium nitride (TiNx).

The thickness of the second bank BNK2 may range from approximately 300 Å to approximately 600 Å, the thickness of the third bank BNK3 may range from approximately 200 Å to approximately 400 Å, and the thickness of the fourth bank BNK4 may range from approximately 100 to approximately 200 Å. It should be understood, however, that the disclosure is not limited thereto. The thickness of the first bank BNK1 may be greater than the sum of the thicknesses of the second to fourth banks BNK2, BNK3 and BNK4, but the disclosure is not limited thereto.

The low-reflection insulating layer BIL may further include first to third layers BIL1, BIL2 and BIL3. The first layer BIL1 may be disposed on the bank BNK, the second layer BIL2 may be disposed on the first layer BIL1, and the third layer BIL3 may be disposed on the second layer BIL2. The first to third layers BIL1, BIL2 and BIL3 may include a material having relatively low reflectance. The first to third layers BIL1, BIL2 and BIL3 may include different inorganic layers. In an embodiment, the first layer BIL1 may include silicon oxynitride (SiONx), the second layer BIL2 may include silicon nitride (SiNx), and the third layer BIL3 may include silicon oxide (SiOx), for example. It should be understood, however, that the disclosure is not limited thereto.

The thickness of the first layer BIL1 may range from approximately 500 Å to approximately 1,500 Å, the thickness of the second layer BIL2 may range from approximately 4,000 Å to approximately 5,000 Å, and the thickness of the third layer BIL3 may range from approximately 4,000 Å to approximately 5,000 Å. It should be understood, however, that the disclosure is not limited thereto. The thickness of the second or third layers BIL2 or BIL3 may be greater than the sum of thicknesses of the second to fourth banks BNK2, BNK3 and BNK4.

The refractive index of the first layer BIL1 may range from approximately 1.7 to approximately 1.8, the refractive index of the second layer BIL2 may range from approximately 1.85 to approximately 1.9, and the refractive index of the third layer BIL3 may range from approximately 1.45 to approximately 1.55. It should be understood, however, that the disclosure is not limited thereto.

A photoresist PR may be disposed on the low-reflection insulating layer BIL such that it does not overlap with the first pixel electrode AE1. The photoresist PR may be disposed except for the area where the first emission area EA1 is to be formed.

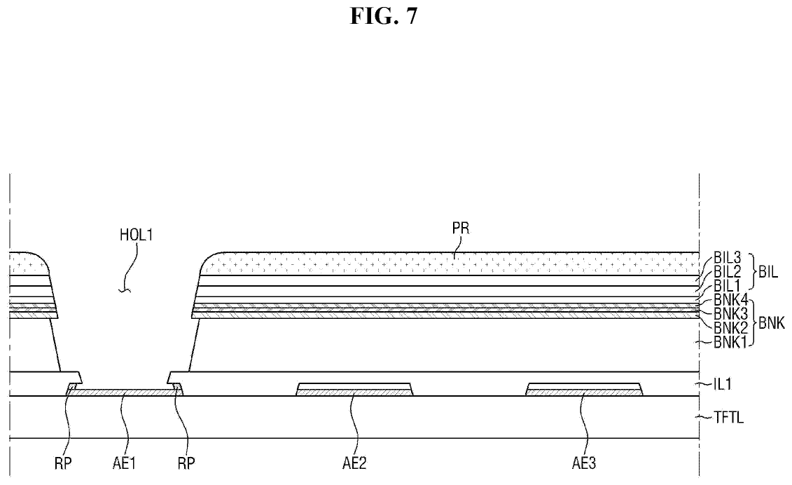

In FIG. 7, the low-reflection insulating layer BIL, the bank BNK, the first insulating layer IL1 and the sacrificial layer SFL may be sequentially etched to define a first hole HOL1. The first hole HOL1 may overlap with the first emission area EA1.

The low-reflection insulating layer BIL and the bank BNK may be etched by performing at least one of a dry etching process and a wet etching process. In an embodiment, the low-reflection insulating layer BIL and the bank BNK may be etched first via a dry etching process and then via a wet etching process, for example. It should be understood, however, that the disclosure is not limited thereto. The first bank BNK1 may include a different metal material from that of the second to fourth banks BNK2, BNK3 and BNK4. The etch rate of the first bank BNK1 may be different from the etch rates of the second to fourth banks BNK2, BNK3 and BNK4. In a wet etching process, the etch rate of the first bank BNK1 may be higher than that of the second to fourth banks BNK2, BNK3 and BNK4, and the first bank BNK1 may be etched more than the second to fourth banks BNK2, BNK3 and BNK4. Accordingly, the shapes of the side surfaces of the first to fourth banks BNK1, BNK2, BNK3 and BNK4 may be determined by a difference in the etch rates between the first to fourth banks BNK1, BNK2, BNK3 and BNK4. The second bank BNK2 may include a tip protruding from the first bank BNK1 toward the first hole HOL1. The side surfaces of the first bank BNK1 may be recessed inward from the side surfaces of the second bank BNK2. An undercut structure may be formed under the tip of the second bank BNK2. The thickness of the first bank BNK1 may be greater than that of the second bank BNK2.

The first insulating layer IL1 and the sacrificial layer SFL may be etched by performing at least one of a dry etching process and a wet etching process. In an embodiment, the first insulating layer IL1 may be etched via a dry etching process and the sacrificial layer SFL may be etched via a wet etching process, for example. It should be understood, however, that the disclosure is not limited thereto. As the first insulating layer IL1 and the sacrificial layer SFL are etched, at least a part of the upper surface of the first pixel electrode AE1 may be exposed. In the wet etching process, the sacrificial layer SFL may be etched more than the first insulating layer IL1 when viewed from the top. After the sacrificial layer SFL has been etched, a remaining pattern RP may remain between the first insulating layer IL1 and the first pixel electrode AE1. Accordingly, the side surfaces of the remaining pattern RP may have a shape recessed inward from the side surfaces of the first insulating layer IL1.

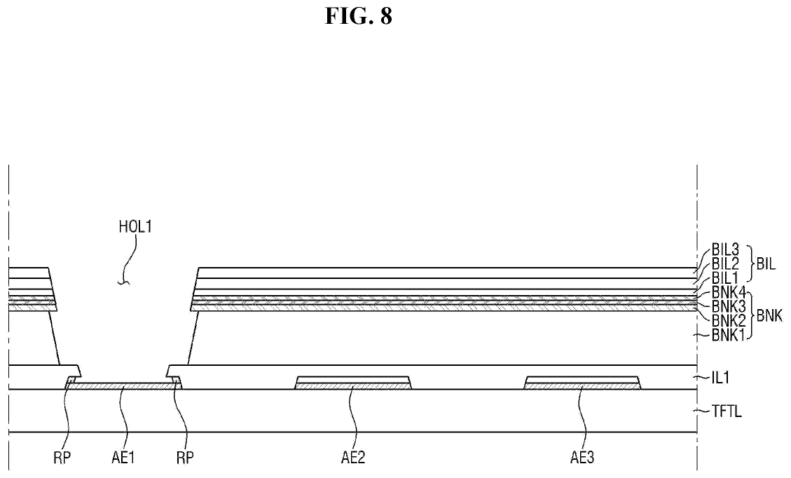

In FIG. 8, the photoresist PR may be removed via a strip process after the first hole HOL1 has been defined.

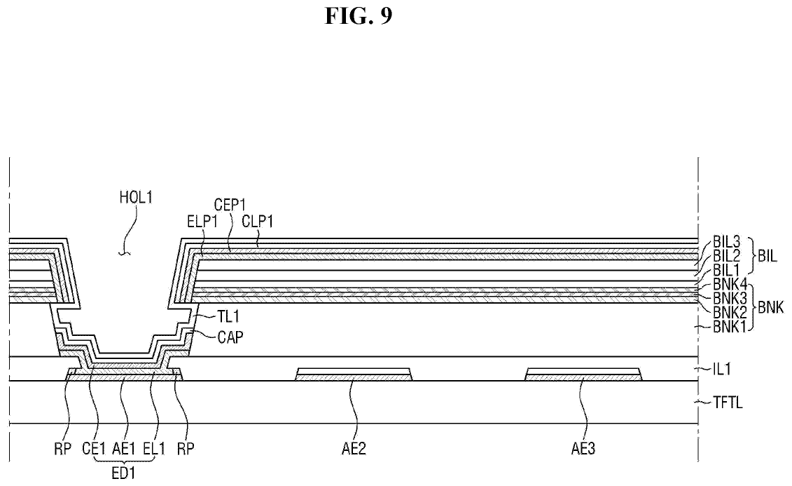

In FIG. 9, the first emissive layer EL1 may be disposed directly on the first pixel electrode AE1 in the first emission area EA1. A part of the first emissive layer EL1 may be disposed in the space surrounded by the first pixel electrode AE1, the remaining pattern RP and the first insulating layer IL1, while other parts of the first emissive layer EL1 may cover a part of the upper surface and side surfaces of the first insulating layer IL1.

An organic material for forming the first emissive layer EL1 and the first organic pattern ELP1 may be deposited on the entirety of the surface of the display device 10. The first organic pattern ELP1 may include the same organic material as that of the first emissive layer EL1 and may be disposed on the low-reflection insulating layer BIL. The first organic pattern ELP1 may cover the side surfaces of the second to fourth banks BNK2, BNK3 and BNK4 and the low-reflection insulating layer BIL which are adjacent to the first emission area EA1. The third emissive layer EL3 and the first organic pattern ELP1 may be deposited via the same process, but may be cut by the tip formed on the inner wall of the bank BNK. Accordingly, the first organic pattern ELP1 may be disposed on the low-reflection insulating layer BIL except the first emission area EA1.

The first common electrode CE1 may be disposed on the first emissive layer EL1. The first common electrode CE1 may include a transparent conductive material and may transmit light generated in the first emissive layer EL1. The first common electrode CE1 may contact the side surfaces of the first bank BNK1. Accordingly, the first light-emitting element ED1 may be formed in the first hole HOL1 and may emit light through the first emission area EA1.

A metal material for forming the first common electrode CE1 and the first electrode pattern CEP1 may be deposited on the entirety of the surface of the display device 10. The first electrode pattern CEP1 may include the same metal material as that of the first common electrode CE1 and may be disposed on the first organic pattern ELP1. The first electrode pattern CEP1 may cover a side surface of the first organic pattern ELP1 which is closer to the first emission area EA1. The first common electrode CE1 and the first electrode pattern CEP1 may be deposited via the same process, but may be cut by the tip formed on the inner wall of the bank BNK. Accordingly, the first electrode pattern CEP1 may be disposed on the first organic pattern ELP1 except the first emission area EA1.

The capping layer CAP may be disposed on the first common electrode CE1. The capping layer CAP may include an inorganic insulating material and may cover the first light-emitting element ED1. The capping layer CAP may prevent the first light-emitting element ED1 from being damaged by external air. In an embodiment, the capping layer CAP may include, but is not limited to, at least one of a silicon nitride layer, a silicon oxynitride layer, a silicon oxide layer, a titanium oxide layer, an aluminum oxide layer, and an amorphous silicon layer, for example.

An inorganic material for forming the capping layer CAP and the first capping pattern CLP1 may be deposited on the entirety of the surface of the display device 10. The first capping pattern CLP1 may include the same inorganic material as that of the capping layer CAP and may be disposed on the first electrode pattern CEP1. The first capping pattern CLP1 may cover a side surface of the first electrode pattern CEP1 which is closer to the first emission area EA1. The capping layer CAP and the first capping pattern CLP1 may be deposited via the same process, but may be cut by the tip formed on the inner wall of the bank BNK. Accordingly, the first capping pattern CLP1 may be disposed on the first electrode pattern CEP1 except the first emission area EA1.

The first inorganic layer TL1 may be disposed on the capping layer CAP of the first emission area EA1 and the first capping pattern CLP1. The first inorganic layer TL1 may cover the side surfaces of the first bank BNK1 surrounding the first emission area EA1. The first inorganic layer TL1 includes an inorganic material to prevent oxygen or moisture from permeating into the first light-emitting element ED1. The first inorganic layer TL1 may be an inorganic encapsulation layer. In an embodiment, the first inorganic layer TL1 may include, but is not limited to, at least one of a silicon nitride layer, a silicon oxynitride layer, a silicon oxide layer, a titanium oxide layer, an aluminum oxide layer, and an amorphous silicon layer, for example.

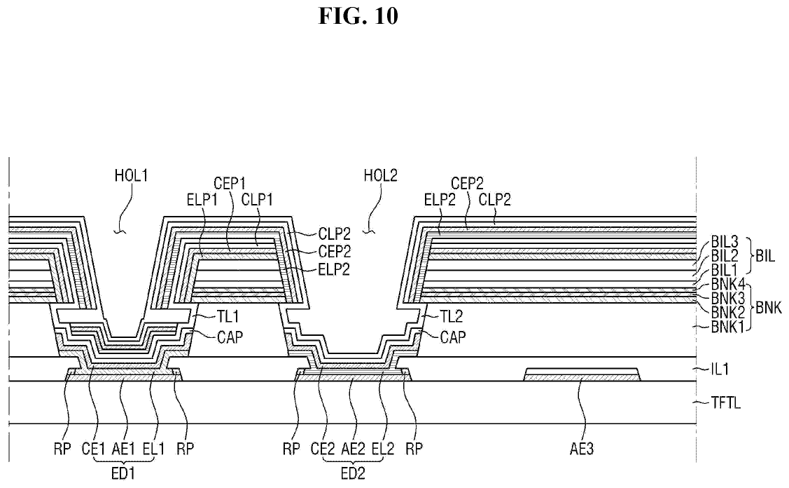

In FIG. 10, a second hole HOL2 may overlap the second emission area EA2. The first inorganic layer TL1, the first capping pattern CLP1, the first electrode pattern CEP1, the first organic pattern ELP1, the low-reflection insulating layer BIL, the bank BNK, the first insulating layer IL1 and the sacrificial layer SFL may be sequentially etched to define the second hole HOL2. In the process of defining the second hole HOL2, the low-reflection insulating layer BIL, the bank BNK, the first insulating layer IL1 and the sacrificial layer SFL may be etched in substantially the same manner as that described above with reference to FIGS. 6 to 8.

The second emissive layer EL2 may be disposed directly on the second pixel electrode AE2 in the second emission area EA2. A part of the second emissive layer EL2 may be disposed in the space surrounded by the second pixel electrode AE2, the remaining pattern RP and the first insulating layer IL1, while other parts of the second emissive layer EL2 may cover a part of the upper surface and side surfaces of the first insulating layer IL1.

An organic material for forming the second emissive layer EL2 and the second organic pattern ELP2 may be deposited on the entirety of the surface of the display device 10. A second organic pattern ELP2 may include the same organic material as that of the second emissive layer EL2 and may be disposed on the first inorganic layer TL1. The second organic pattern ELP2 may cover the side surfaces of the second to fourth banks BNK2, BNK3 and BNK4, the low-reflection insulating layer BIL, the first organic pattern ELP1, the first electrode pattern CEP1, the first capping pattern CLP1 and the first inorganic layer TL1, which are adjacent to the second emission area EA2. The second emissive layer EL2 and the second organic pattern ELP2 may be deposited via the same process, but may be cut by the tip formed on the inner wall of the bank BNK. Accordingly, the second organic pattern ELP2 may be disposed on the first inorganic layer TL1 except the second emission area EA2.

The second common electrode CE2 may be disposed on the second emissive layer EL2. The second common electrode CE2 may include a transparent conductive material and may transmit light generated in the second emissive layer EL2. The second common electrode CE2 may contact the side surfaces of the first bank BNK1. Accordingly, the second light-emitting element ED2 may be formed in the second hole HOL2 and may emit light through the second emission area EA2.

A metal material for forming the second common electrode CE2 and the second electrode pattern CEP2 may be deposited on the entirety of the surface of the display device 10. The second electrode pattern CEP2 may include the same metal material as that of the second common electrode CE2 and may be disposed on the second organic pattern ELP2. The second electrode pattern CEP2 may cover a side surface of the second organic pattern ELP2 which is closer to the second emission area EA2. The second common electrode CE2 and the second electrode pattern CEP2 may be deposited via the same process, but may be cut by the tip formed on the inner wall of the bank BNK. Accordingly, the second electrode pattern CEP2 may be disposed on the second organic pattern ELP2 except the second emission area EA2.

The capping layer CAP may be disposed on the second common electrode CE2. The capping layer CAP may include an inorganic insulating material and may cover the second light-emitting element ED2. The capping layer CAP may prevent the second light-emitting element ED2 from being damaged by external air.

An inorganic material for forming the capping layer CAP and the second capping pattern CLP2 may be deposited on the entirety of the surface of the display device 10. The second capping pattern CLP2 may include the same inorganic material as that of the capping layer CAP and may be disposed on the second electrode pattern CEP2. The second capping pattern CLP2 may cover a side surface of the second electrode pattern CEP2 which is closer to the second emission area EA2. The capping layer CAP and the second capping pattern CLP2 may be deposited via the same process, but may be cut by the tip formed on the inner wall of the bank BNK. Accordingly, the second capping pattern CLP2 may be disposed on the second electrode pattern CEP2 except the second emission area EA2.

The second inorganic layer TL2 may be disposed on the capping layer CAP of the second emission area EA2 and the second capping pattern CLP2. The second inorganic layer TL2 may cover the side surfaces of the first bank BNK1 surrounding the second emission area EA2. The second inorganic layer TL2 includes an inorganic material to prevent oxygen or moisture from permeating into the second light-emitting element ED2. The second inorganic layer TL2 may be an inorganic encapsulation layer. In an embodiment, the second inorganic layer TL2 may include or consist of any of the above-listed materials for the first inorganic layer TL1, for example.

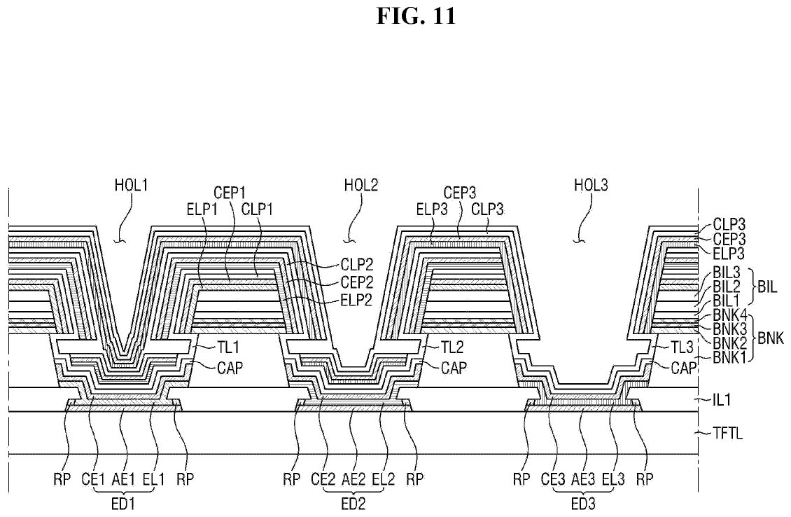

In FIG. 11, a third hole HOL3 may overlap the third emission area EA3. The second inorganic layer TL2, the second capping pattern CLP2, the second electrode pattern CEP2, the second organic pattern ELP2, the first inorganic layer TL1, the first capping pattern CLP1, the first electrode pattern CEP1, the first organic pattern ELP1, the low-reflection insulating layer BIL, the bank BNK, the first insulating layer IL1 and the sacrificial layer SFL may be sequentially etched to form the third hole HOL3. In the process of defining the third hole HOL3, the low-reflection insulating layer BIL, the bank BNK, the first insulating layer IL1 and the sacrificial layer SFL may be etched in substantially the same manner as that described above with reference to FIGS. 6 to 8.

The third emissive layer EL3 may be disposed directly on the third pixel electrode AE3 in the third emission area EA3. A part of the third emissive layer EL3 may be disposed in the space surrounded by the third pixel electrode AE3, the remaining pattern RP and the first insulating layer IL1, while other parts of the third emissive layer EL3 may cover a part of the upper surface and side surfaces of the first insulating layer IL1.

An organic material for forming the third emissive layer EL3 and the third organic pattern ELP3 may be deposited on the entirety of the surface of the display device 10. The third organic pattern ELP3 may include the same organic material as that of the third emissive layer EL3 and may be disposed on the second inorganic layer TL2. The third organic pattern ELP3 may cover the side surfaces of the second to fourth banks BNK2, BNK3 and BNK4, the low-reflection insulating layer BIL, the first organic pattern ELP1, the first electrode pattern CEP1, the first capping pattern CLP1, the first inorganic layer TL1, the second organic pattern ELP2, the second electrode pattern CEP2, the second capping pattern CLP2 and the second inorganic layer TL2, which are adjacent to the third emission area EA3. The third emissive layer EL3 and the third organic pattern ELP3 may be deposited via the same process, but may be cut by the tip formed on the inner wall of the bank BNK. Accordingly, the third organic pattern ELP3 may be disposed on the second inorganic layer TL2 except the third emission area EA3.

The third common electrode CE3 may be disposed on the third emissive layer EL3. The third common electrode CE3 may include a transparent conductive material and may transmit light generated in the third emissive layer EL3. The third common electrode CE3 may contact the side surfaces of the first bank BNK1. Accordingly, the third light-emitting element ED3 may be formed in the third hole HOL3 and may emit light through the third emission area EA3.

A metal material for forming the third common electrode CE3 and the third electrode pattern CEP3 may be deposited on the entirety of the surface of the display device 10. The third electrode pattern CEP3 may include the same metal material as that of the third common electrode CE3 and may be disposed on the third organic pattern ELP3. The third electrode pattern CEP3 may cover a side surface of the third organic pattern ELP3 which is closer to the third emission area EA3. The third common electrode CE3 and the third electrode pattern CEP3 may be deposited via the same process, but may be cut by the tip formed on the inner wall of the bank BNK. Accordingly, the third electrode pattern CEP3 may be disposed on the third organic pattern ELP3 except the third emission area EA3.

The capping layer CAP may be disposed on the third common electrode CE3. The capping layer CAP may include an inorganic insulating material and may cover the third light-emitting element ED3. The capping layer CAP may prevent the third light-emitting element ED3 from being damaged by external air.

An inorganic material for forming the capping layer CAP and the third capping pattern CLP3 may be deposited on the entirety of the surface of the display device 10. The third capping pattern CLP3 may include the same inorganic material as that of the capping layer CAP and may be disposed on the third electrode pattern CEP3. The third capping pattern CLP3 may cover a side surface of the third electrode pattern CEP3 which is closer to the third emission area EA3. The capping layer CAP and the third capping pattern CLP3 may be deposited via the same process, but may be cut by the tip formed on the inner wall of the bank BNK. Accordingly, the third capping pattern CLP3 may be disposed on the third electrode pattern CEP3 except the third emission area EA3.

The third inorganic layer TL3 may be disposed on the capping layer CAP of the third emission area EA3 and the third capping pattern CLP3. The third inorganic layer TL3 may cover the side surfaces of the first bank BNK1 surrounding the third emission area EA3. The third inorganic layer TL3 includes an inorganic material to prevent oxygen or moisture from permeating into the third light-emitting element ED3. The third inorganic layer TL3 may be an inorganic encapsulation layer. In an embodiment, the third inorganic layer TL3 may include or consist of any of the above-listed materials for the first inorganic layer TL1, for example.

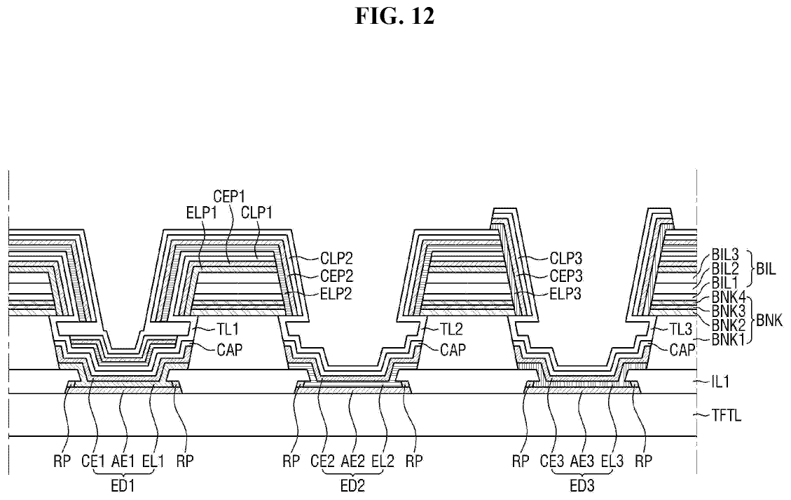

In FIG. 12, the third inorganic layer TL3, the third capping pattern CLP3, the third electrode pattern CEP3 and the third organic pattern ELP3 may be etched sequentially in the first emission area EA1 and the vicinity, and in the second emission area EA2 and the vicinity. The third inorganic layer TL3, the third capping pattern CLP3, the third electrode pattern CEP3 and the third organic pattern ELP3 may remain in the third emission area EA3 and the vicinity. The third inorganic layer TL3, the third capping pattern CLP3, the third electrode pattern CEP3 and the third organic pattern ELP3 may be etched by performing at least one of the dry etching process and the wet etching process.

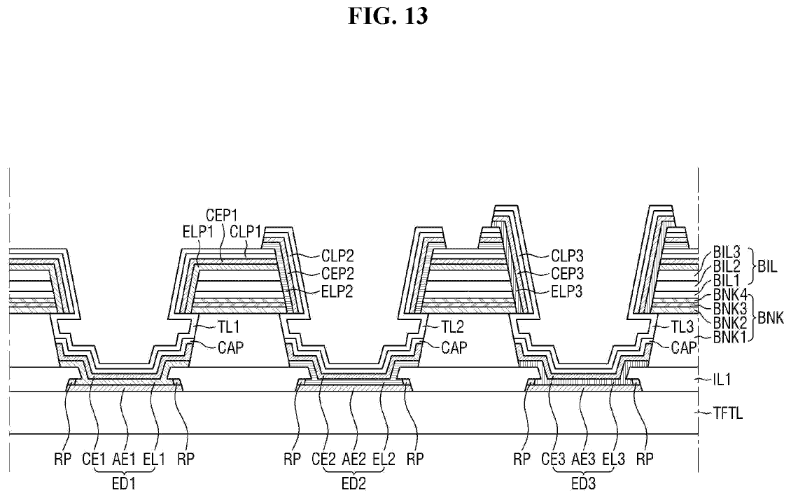

In FIG. 13, the second inorganic layer TL2, the second capping pattern CLP2, the second electrode pattern CEP2 and the second organic pattern ELP2 may be etched sequentially in the first emission area EA1 and the vicinity. The second inorganic layer TL2, the second capping pattern CLP2, the second electrode pattern CEP2 and the second organic pattern ELP2 may remain in the first emission area EA1 and the vicinity. The second inorganic layer TL2, the second capping pattern CLP2, the second electrode pattern CEP2 and the second organic pattern ELP2 may be etched by performing at least one of the dry etching process and the wet etching process.

What is claimed is:

1. A display device comprising:
a first pixel electrode disposed in a first emission area on a substrate;
an insulating layer covering an edge of the first pixel electrode;
a first emissive layer disposed on the first pixel electrode and the insulating layer;
a first common electrode disposed on the first emissive layer;
a bank disposed on the insulating layer and surrounding the first emission area, the bank comprising:
a first bank disposed on the insulating layer and in contact with the first common electrode;
a second bank disposed on the first bank;
a third bank disposed on the second bank; and
a fourth bank disposed on the third bank;
a low-reflection insulating layer disposed on the bank;
a first organic pattern surrounding the first emission area on the low-reflection insulating layer and including a same material as a material of the first emissive layer,
wherein the first to fourth banks include metal materials.

2. The display device of claim 1, wherein the first bank includes aluminum, the second bank includes titanium, the third bank includes titanium oxide or aluminum nitride, and the fourth bank includes titanium or titanium nitride.

3. The display device of claim 1, wherein a thickness of the first bank is greater than a sum of thicknesses of the second to fourth banks.

4. The display device of claim 3, wherein the thickness of the second bank ranges from approximately 300 angstroms to approximately 600 angstroms, the thickness of the third bank ranges from approximately 200 angstroms to approximately 400 angstroms, and the thickness of the fourth bank ranges from approximately 100 angstroms to approximately 200 angstroms.

5. The display device of claim 1, wherein a side surface of the first bank is recessed inward from a side surface of the second bank.

6. The display device of claim 1, wherein the low-reflection insulating layer comprises:
a first layer disposed on the fourth bank;
a second layer disposed on the first layer; and
a third layer disposed on the second layer.

7. The display device of claim 6, wherein the first to third layers include different inorganic layers from each other.

8. The display device of claim 6, wherein the first layer includes silicon oxynitride, the second layer includes silicon nitride, and the third layer includes silicon oxide.

9. The display device of claim 6, wherein a thickness of the first layer ranges from approximately 500 angstroms to approximately 1,500 angstroms, a thickness of the second layer ranges from approximately 4,000 angstroms to approximately 5,000 angstroms, and a thickness of the third layer ranges from approximately 4,000 angstroms to approximately 5,000 angstroms.

10. The display device of claim 6, wherein the first layer has a refractive index of approximately 1.7 to approximately 1.8, the second layer has a refractive index of approximately 1.85 to approximately 1.9, and the third layer has a refractive index of approximately 1.45 to approximately 1.55.

11. The display device of claim 6, wherein a thickness of the second or third layer is greater than a sum of thicknesses of the second to fourth banks.

12. The display device of claim 1, further comprising:
a second pixel electrode disposed in a second emission area on the substrate;
a second emissive layer disposed on the second pixel electrode; and
a second common electrode disposed on the second emissive layer.

13. The display device of claim 12, wherein the first and second common electrodes are electrically connected with each other through the first bank.

14. A method of fabricating a display device, the method comprising:
forming first and second pixel electrodes on a substrate;
stacking a sacrificial layer, an insulating layer, a bank and a low-reflection insulating layer on the first and second pixel electrodes;
exposing the first pixel electrode by etching the low-reflection insulating layer, the bank, the insulating layer and the sacrificial layer; and
forming a first emissive layer on the first pixel electrode and forming a first organic pattern on the low-reflection insulating layer,
wherein the bank comprises:
a first bank disposed on the insulating layer and in contact with a first common electrode;
a second bank disposed on the first bank;
a third bank disposed on the second bank; and
a fourth bank disposed on the third bank, and
wherein the first to fourth banks include metal materials.

15. The method of claim 14, wherein the exposing the first pixel electrode comprises etching a side surface of the first bank more than a side surface of the second bank to form a protruding tip of the second bank.

16. The method of claim 15, wherein the forming the first emissive layer and forming the first organic pattern comprises cutting an organic material deposited on the substrate by the protruding tip of the second bank to separate the first emissive layer and the first organic pattern from each other.

17. The method of claim 14, wherein the first bank includes aluminum, the second bank includes titanium, the third bank includes titanium oxide or aluminum nitride, and the fourth bank includes titanium or titanium nitride.

18. The method of claim 14, wherein the thickness of the second bank ranges from approximately 300 angstroms to approximately 600 angstroms, the thickness of the third bank ranges from approximately 200 angstroms to approximately 400 angstroms, and the thickness of the fourth bank ranges from approximately 100 angstroms to approximately 200 angstroms.

19. The method of claim 14, wherein the low-reflection insulating layer comprises:
a first layer disposed on the fourth bank;
a second layer disposed on the first layer; and
a third layer disposed on the second layer.

20. The method of claim 19, wherein the first layer includes silicon oxynitride, the second layer includes silicon nitride, and the third layer includes silicon oxide.
